(19) United States
(12) Patent Application Publication
(10) Pub. No.: US 2010/0025580 A1
(43) Pub. Date: Feb. 4, 2010

(54) GRID HOLDER FOR STEM ANALYSIS IN A CHARGED PARTICLE INSTRUMENT

(75) Inventors: Matthew Hammer, Dallas, TX (US); Gonzalo Amador, Dallas, TX (US)

Correspondence Address: Glast, Phillips & Murray, P.C, 13355 Noel Road, Suite 2200, Dallas, TX, 75240, US

(73) Assignee: Omniprobe, Inc., Dallas, TX (US)

(21) Appl. No.: 12/533,565

(22) Filed: Jul. 31, 2009

Related U.S. Application Data
(60) Provisional application No. 61/085,630, filed on Aug. 1, 2008.

(51) Int. Cl. H01J 37/26; H01J 37/20

(52) U.S. Cl. 250/311; 250/442.11

(57) ABSTRACT

A grid holder for STEM analysis in a charged-particle instrument has a base jaw and a pivoting jaw. Both jaws have a substantially congruent inclined portion. The base jaw has a flat portion for mounting the holder on the sample carousel of a charged-particle instrument, such as a dual beam FIB. The inclined portion of the jaws is inclined to the flat portion of the holder at an angle A approximately equal to the difference between 90 degrees and the angle between the electron beam and the ion beam in the charged-particle instrument. The inclined portion of the jaws has a pocket for receiving and holding a sample grid. When a sample is mounted on the grid and the grid is held by the grid holder, the sample will be correctly oriented for ion-beam thinning when the sample carousel is horizontal. The thinned sample may then be placed perpendicular to the electron beam for STEM analysis by tilting the sample carousel by the same angle A.

### CROSS-REFERENCE TO RELATED APPLICATIONS

This application is related to co-pending U.S. patent applications, Ser. No. 12/041,217, filed Mar. 3, 2008 and Ser. No. 12/509/187, filed Jul. 24, 2009.

### CLAIM FOR PRIORITY

This application claims the priority of U.S. provisional patent application, Ser. No. 61/085,630, filed Aug. 1, 2008, and entitled “STEM Grid Holder and Method for Its Use in a Dual-Beam FIB Instrument,” which provisional application is incorporated by reference into the present application.

### BACKGROUND

This application relates to sample preparation and inspection inside a charged-particle beam instrument, such as a dual-beam focused-ion beam microscope, called a “DB-FIB” or “FIB” in this application.

The use of focused ion-beam (FIB) microscopes has become common for the preparation of specimens for later analysis in a transmission electron microscope (TEM) or scanning transmission electron microscope (STEM), and the in-situ lift-out technique has become the method of choice for the preparation of a tiny sample for TEM inspection. TEM and STEM inspection offer fine image resolution (<0.1 nm), but require electron-transparent (<100 nm thick) sections of the sample. TEM and STEM inspection usually takes place in a separate TEM or STEM device, which requires the transfer of a fragile TEM sample to another location. Dual-beam (DB-FIB) instruments are being more widely used for TEM sample preparation and inspection. The DB-FIB instrument combines high-resolution imaging of the SEM and FIB in the same chamber allows for the location, preparation, and inspection of samples in the same microscope.

The electron beam within the DB-FIB can substitute for a conventional STEM beam, and a transmitted electron detector, located beneath the sample in the DB-FIB, enables in-situ STEM imaging of a sample. This system provides an increased throughput at reduced cost per sample for failure analysis and process control applications requiring STEM analysis. Applying in-situ lift-out technology in the DB-FIB provides a means for excising tiny samples from a specimen and positioning them on TEM sample holder or grid, using the special features of a nano-manipulator device, for later inspection within the DB-FIB. A suitable nano-manipulator system is the Omniprobe AutoProbe 200™, manufactured by Omniprobe, Inc., of Dallas, Tex.

After the sample is excised from the specimen, it is attached to the TEM grid and is ready for further investigation. There is a need for a grid holder that will allow both thinning of the bulk sample by the DB-FIB ion beam and STEM analysis under the DB-FIB electron beam, while minimizing the number of changes of the orientation of the DB-FIB tilt stage or of the sample holder.

### DRAWINGS

FIG. 1 shows a perspective view of an embodiment of an STEM grid holder of present application in the closed state with a TEM grid placed between jaws.

FIG. 2 shows a cross-sectional view of an embodiment of an STEM grid holder in the closed state.

FIG. 3 shows a partial enlarged perspective view of an embodiment of an STEM grid holder in the open state.

FIG. 4 shows a top view of a sample carousel with an embodiment of an STEM holder mounted on it.

FIG. 5 shows a perspective view of an embodiment of an STEM holder attached to the sample carousel.

FIG. 6 shows a flowchart of an exemplary method of STEM analysis using an embodiment of the STEM holder.

FIG. 7 shows a schematic view of a DB-FIB system showing the process of FIB thinning of a TEM sample attached to a TEM grid, where the TEM grid is held by the STEM grid holder.

FIG. 8 shows a schematic view of a DB-FIB system showing the process of STEM analysis of a TEM sample attached to the TEM grid held by the STEM grid holder.

### DESCRIPTION

The embodiments disclosed here include a novel method and apparatus for the process of immediate STEM analysis performed inside a dual-beam FIB microscope using an STEM grid holder mounted on the FIB sample carousel. The field of application is not limited to dual-beam FIB systems or to semiconductor samples; applications could include, for example, nano-mechanical systems or biological samples.

The method and apparatus of this application provide for higher throughput STEM inspection within the DB-FIB because the sample does not have to be removed from the microscope and no additional axes of motion are added to the system to enable STEM imaging.

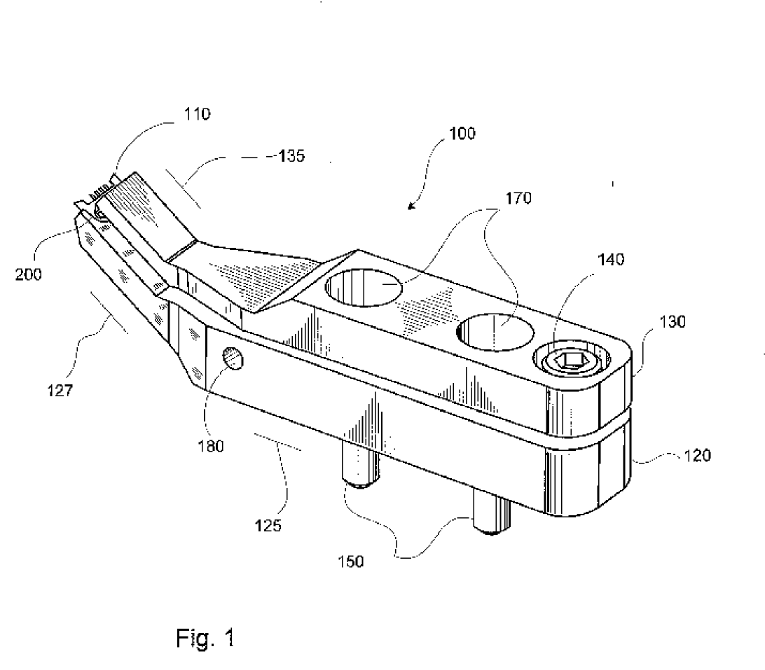

FIG. 1 shows an embodiment of the STEM grid holder (100) comprising the following elements: a base jaw (120), a moving pivoting jaw (130), a jaw adjusting screw (140), mounting screws (150), and a pivoting joint as described below. The approximate dimensions of the assembled STEM grid holder are 25 mm×5.1 mm×6.2 mm. The material is preferably aluminum, but may also be any non-magnetic material. This embodiment of the STEM grid holder (100) allows the TEM sample to be as close as 1.5 mm to the electron beam column (250). This proximity helps obtain the best quality of STEM images. The embodiment shown is designed to hold a standard TEM grid, although other embodiments of the STEM grid holder can hold grids or assemblies of other shapes having the about same size as the standard TEM grid (110). An example of such an assembly could be a probe tip point bearing a sample and attached to the TEM grid as described in U.S. Pat. No. 7,115,882.

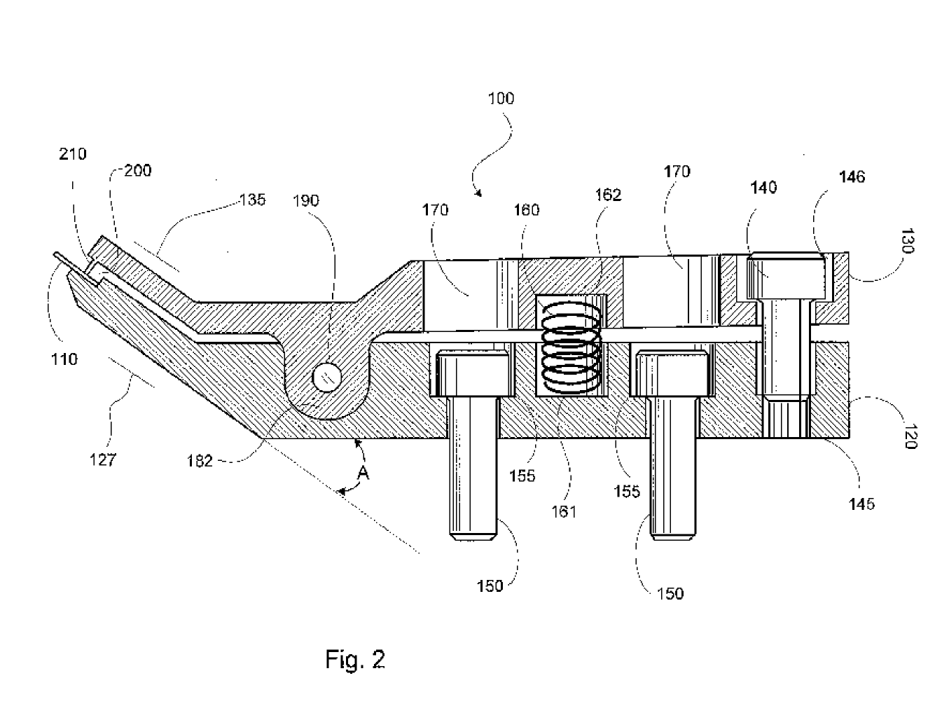

FIG. 2 is a cross-sectional view of an embodiment of the STEM grid holder (100), showing details of its inner structure. The base jaw (120) has two holes (155) for the mounting means, such as mounting screws (150), a tapped hole (145) for the jaw adjusting screw (140), an opening (180) for the pivot pin (190) (not shown in FIG. 1) and a first cavity (161) for a spring (160). The holes (155) are located so that the base jaw (120) may be mounted on the sample carousel (220) of a FIB instrument. Although the base jaw (120) is shown as a solid piece, it can be envisioned as having two parts: a flat portion (125) having the mounting holes (155) for mounting the grid holder (100) on the sample carousel (220), and an inclined portion (127), extending from the flat portion (125) and having a pocket (200) for holding a TEM grid (110). The inclined portion (127) is inclined at an angle A to the flat portion (125) of the base jaw (120) of the STEM grid holder (100). Since the flat portion (125) of the base jaw (120) is mounted on the sample carousel (220) of the FIB, the inclination of the inclined portion (127) sets the proper orientation of the TEM grid (110) relative to the ion beam column (230) for thinning a TEM sample attached to the TEM grid (110), as explained below.

The pivoting jaw (130) has an opening (146) for the jaw adjusting screw (140) and a second spring cavity (162) for the spring (160) corresponding to the first cavity (161) for the spring (160) in the base jaw (120). Also, the pivoting jaw (130) comprises a pivot flange (182), having a pivot opening (180) for a pivot pin (190). The pivoting jaw (130) has an pivoting jaw inclined portion (135) to correspond with the inclined portion (127) of the base jaw (120), the inclined portions (127, 135) being substantially congruent with one another. The pivoting jaw (130) and the base jaw (120) have corresponding mounting screw openings (170).

Angle A is generally peculiar to the particular FIB instrument in use. For example, for the Model 1540 Cross-Beam DB-FIB, manufactured by Carl Zeiss, Inc., angle A would be approximately 36 degrees, because in that instrument, the ion beam column (230) is fixed at an angle of 54 degrees from the vertical. The latter angle will usually be different in other DB-FIB microscopes. In any case, the angle A will be approximately equal to the difference between 90 degrees and the angle between the ion beam (240) and the electron beam (260) for a given instrument, assuming the usual case where the electron beam (260) is vertical with respect to the horizontal of the FIB instrument.

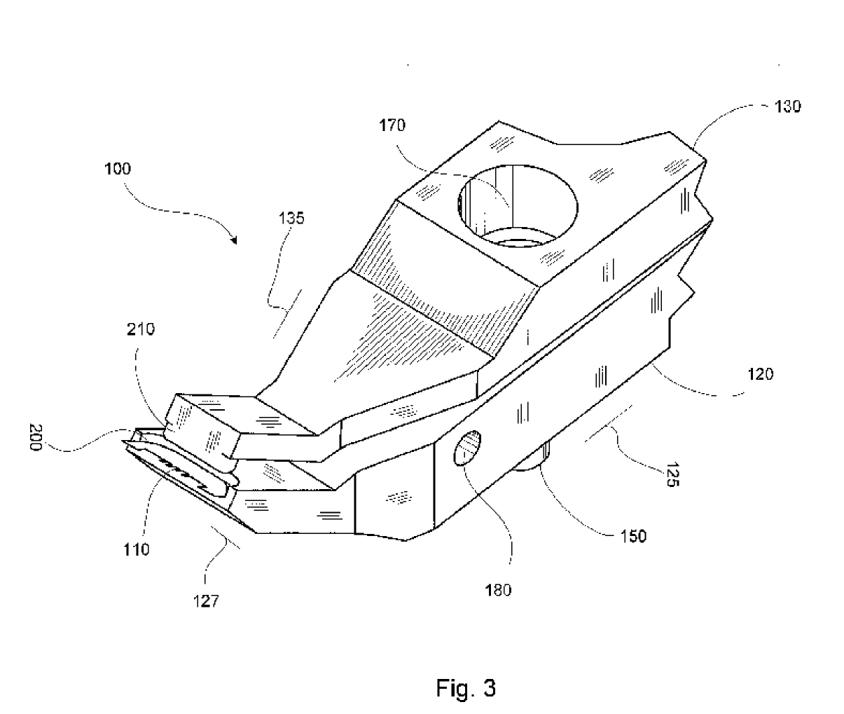

The inclined portion (135) of the pivoting jaw (130) further comprises a small extension (210) that serves to hold the TEM grid (110) inside the pocket (200) as shown in FIG. 3. FIG. 3 also shows that the pocket (200) is oriented so that the plane of the TEM grid (110) is oriented at substantially the same angle as the angle between the base jaw inclined portion (127) and the base jaw flat portion (125), this being the angle A. FIGS. 1 and 2 show the closed state of the holder (100), while FIG. 3 shows its open state.

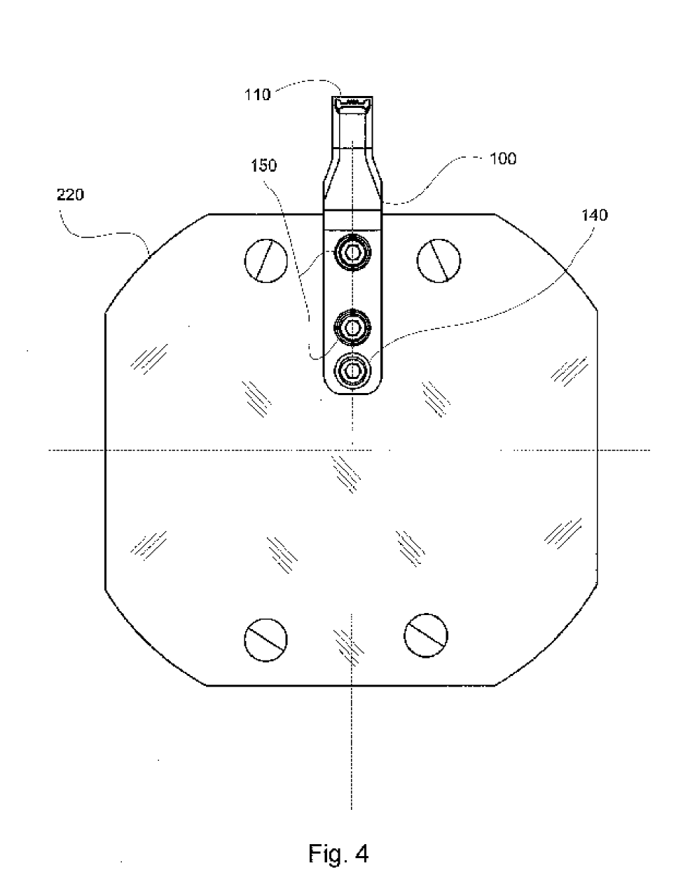

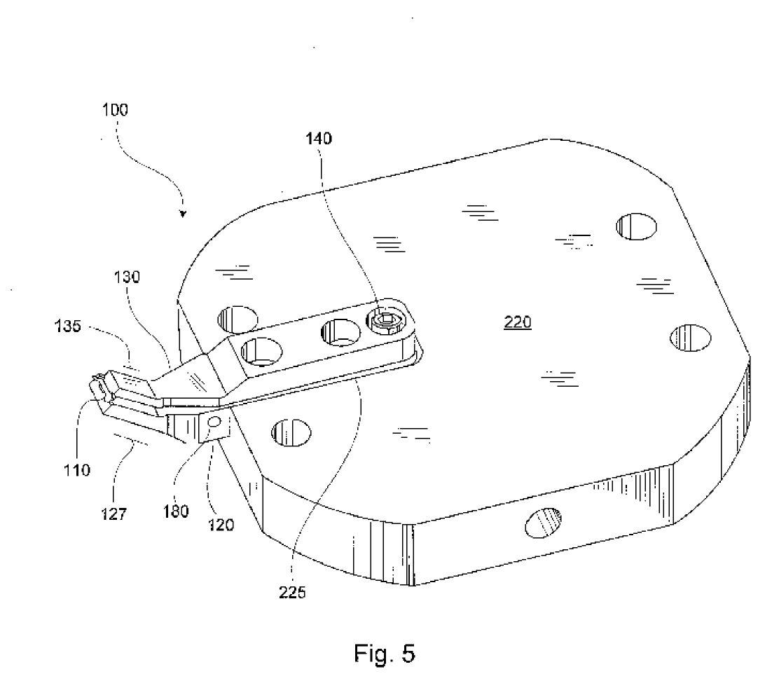

FIG. 4 is a top view of the sample carousel (220) in a FIB instrument with the STEM grid holder (100) mounted on it. The sample carousel (220) shown is typical for Model 1540 Cross-Beam DB-FIB, manufactured by Carl Zeiss, Inc. However, the STEM grid holder (100) can be mounted on any other standard sample holder (220), such as those manufactured by FEI Company, JEOL or others. FIG. 5 is a perspective view of the sample carousel (220) with the STEM grid holder (100) mounted on it. In the example in FIG. 5, the STEM grid holder (100) is recessed into a slot (225) the sample carousel (220), although this configuration is not required.

The STEM grid holder (100) can be assembled and mounted on the sample carousel (220) outside the DB-FIB and placed into the DB-FIB chamber pre-loaded with a TEM grid (110). The assembly process comprises of putting together both jaws (120) and (130), securing the spring (160) in both jaws, securing the pivot pin (190) in its opening (180), and inserting the mounting screws (150) and jaw adjusting screws (140) in their openings. After the assembly is completed, the STEM grid holder (100) can be mounted on the FIB sample carousel (220) using mounting screws (150). The regular operating position of the STEM grid holder (100) is closed, because the jaws (120, 130) are urged together by the captive spring (160).

To load the TEM grid (110) into its pocket (200), the STEM grid holder (100) can be opened by pressing down the edge of the wide flat part of the moving jaw (130) using any suitable rod or even a finger. After the edge is pressed down, the spring (160) is compressed, and the moving jaw is rotated around the pivot. The edge of the inclined portion (127) of the moving jaw moves upwards allowing the TEM grid (110) to be placed into the pocket (200). After the TEM grid (110) is placed into the pocket (200), the inner edge of the moving jaw (130) can be released, and the moving jaw (130) returns to the closed state, securing the TEM grid (110) in the pocket (200) by the light force of the compression spring (160). Alternatively, the jaw adjusting screw (140) can be rotated clockwise to engage the free end of the pivoting jaw (130) causing it to pivot and stay open. Once a TEM grid (110) is loaded, backing out the jaw adjusting screw (140) allows the moving jaw (130) to close.

Multiple STEM grid holders (100) can be mounted on the sample carousel (220), the number depending on the availability of mounting sites for a mounted on the sample carousel (220), it can be loaded into the DB-FIB using the standard loading procedure.

### Method

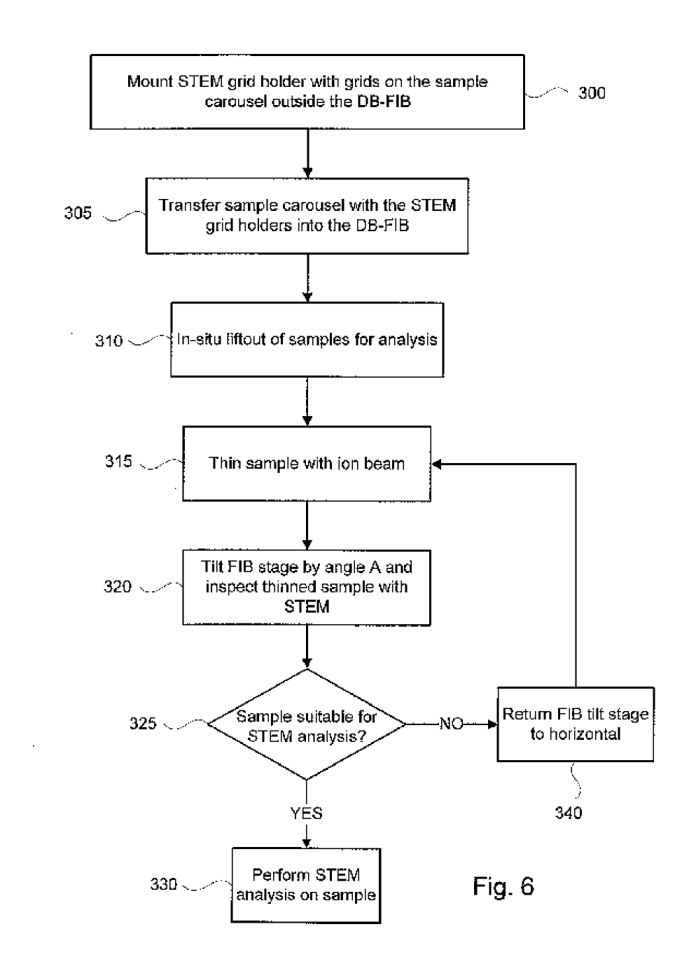

FIG. 6 shows exemplary steps for STEM sample analysis using the STEM grid holder (100) disclosed here. At step 300, at least one STEM grid holder (100) is mounted on the sample carousel (220) outside the DB-FIB. After mounting, a TEM grid (110) is loaded into the pocket (200). The, at step 305, the sample carousel (220) is transferred into the DB-FIB. At step 310, the in-situ lift-out process is performed using methods known in the art. As a part of the in-situ lift-out, the TEM sample is attached to the TEM grid (110). Thereafter, the stage tilt may be returned to horizontal or zero-tilt, and the TEM sample attached to the TEM grid (110).

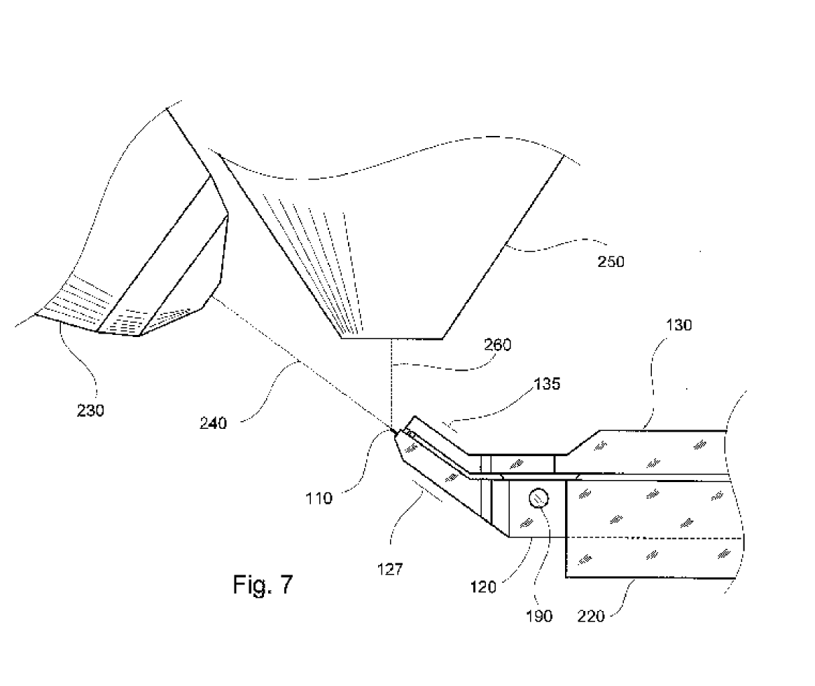

FIG. 7 is an inner view of the DB-FIB chamber showing the ion beam column (230), the electron beam column (250) and a partial view of the STEM grid holder (100), mounted on the sample carousel (220). FIG. 7 shows the FIB tilt stage, and thus the sample carousel (220), at zero tilt.

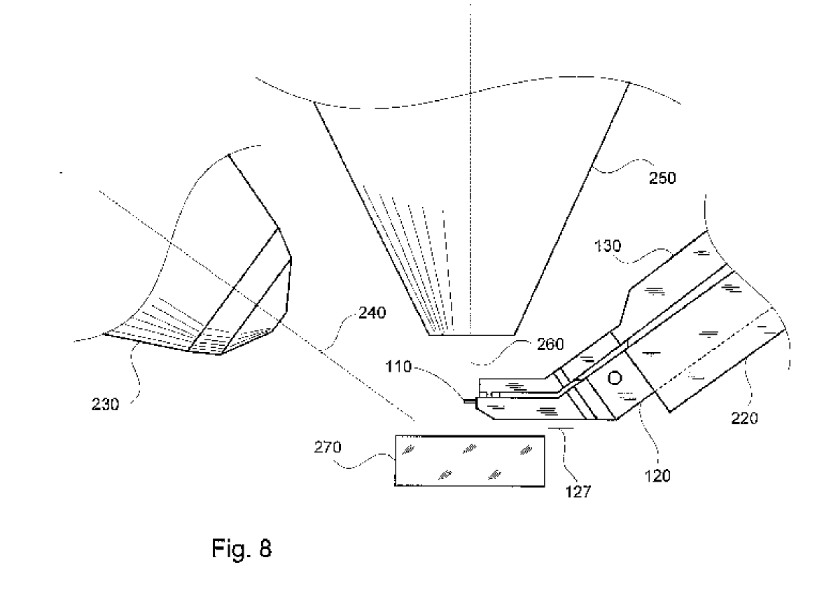

The resulting orientation of the TEM sample allows immediate FIB sample thinning at step 315 with no need for adjustment, because the TEM sample, held at angle A relative to the sample carousel (220), will be substantially parallel to the axis of the ion beam (240). After the FIB thinning of the TEM sample appears to be complete, the sample carousel is tilted by angle A at step 320, thus placing the thinned face of the TEM sample approximately perpendicular to the electron beam (260) for STEM inspection. This orientation is shown in FIG. 8.

If the quality of STEM image is deemed not satisfactory at step 325, the sample stage can be returned to zero-degree tilt orientation at step 340, and the TEM sample can be re-thinned at step 315. The process can be repeated as many times as needed to obtain a satisfactory sample for STEM analysis. If the thinned TEM sample is satisfactory, STEM analysis may be performed at step 330.

If several STEM grid holders (100) are mounted on the sample carousel (220), the transition to the next STEM grid holder (100) can be performed via simple rotation of the sample stage (220). The process will be repeated starting with step 315. The sample carousel (220) may be transferred outside the DB-FIB for optional additional TEM analysis when desired.

None of the description in this application should be read as implying that any particular element, step, or function is an essential element that must be included in the claim scope; the scope of patented subject matter is defined only by the allowed claims. Moreover, none of these claims are intended to invoke paragraph six of 35 USC section 112 unless the exact words “means for” are used, followed by a gerund. The claims as filed are intended to be as comprehensive as possible, and no subject matter is intentionally relinquished, dedicated, or abandoned.

We claim:

1. A grid holder for STEM analysis in a charged-particle instrument; the charged-particle instrument comprising an electron beam and an ion beam, the charged-particle instrument having an angle between the electron beam and the ion beam; the grid holder comprising:
a base jaw;
the base jaw having a base jaw inclined portion and a base jaw flat portion;
the angle between the base jaw inclined portion and the base jaw flat portion being approximately equal to the difference between 90 degrees and the angle between the electron beam and the ion beam in the charged-particle instrument;
a pivoting jaw;
the pivoting jaw having a pivoting jaw inclined portion substantially congruent with the base jaw inclined portion;
a pivot;
the pivot pivotably connecting the base jaw and the pivoting jaw; and
a pocket for receiving a grid, where the grid has a plane;
the pocket disposed in the base jaw inclined portion;
the pocket disposed so that the grid is held in the pocket by the pivoting jaw when the pivoting jaw pivots against the base jaw; and,
the pocket disposed so that the plane of the grid is oriented at substantially the same angle as the angle between the base jaw inclined portion and the base jaw flat portion.

2. The grid holder of claim 1, further comprising;
the charged-particle instrument further comprising a sample carousel; and
the base jaw having mounting holes for mounting the grid holder to the sample carousel.

3. The grid holder of claim 1, further comprising:
a spring;
a first cavity for receiving the spring in the base jaw;
a second cavity for receiving the spring in the pivoting jaw;
so that the spring urges together the inclined portion of the base jaw and the inclined portion of the pivoting jaw.

4. The grid holder of claim 3, further comprising:
a jaw adjusting screw for adjusting the position of the pivoting jaw with respect to the base jaw.

5. The grid holder of claim 1 where the pocket is sized to receive a standard transmission-electron microscope grid.
